(19) United States
(12) Patent Application Publication
(10) Pub. No.: US 2026/0363058 A1
(43) Pub. Date: Nov. 12, 2026

(54) TOP VIA STRUCTURE FOR SEMICONDUCTOR DEVICE

(71) Applicant: International Business Machines Corporation, Armonk, NY (US)

(72) Inventors: Kamal Rudra, Albany, NY (US); Koichi Motoyama, Clifton Park, NY (US); Kisik Choi, Watervliet, NY (US); Ruilong Xie, Niskayuna, NY (US)

(21) Appl. No.: 19/089,183

(22) Filed: Mar. 25, 2025

(51) Int. Cl. H10W 20/48; H10W 20/42; H10W 20/44

(52) U.S. Cl. CPC H10W 20/48; H10W 20/42; H10W 20/4441

(57) ABSTRACT

A semiconductor device is provided. The semiconductor device includes a substrate, a plurality of metal lines on the substrate, a plurality of top vias formed on the plurality of metal lines, and a dielectric liner layer formed on at least portions of the plurality of top vias.

### BACKGROUND

The present disclosure relates to fabrication methods and resulting structures for semiconductor devices. More specifically, the present disclosure relates to interconnect structures including a top via structure. The present disclosure also provides methods of fabricating such an interconnect structure.

The speed of propagation of interconnect signals is one of the most important factors controlling overall circuit speed as feature sizes are reduced and the number of devices per unit area as well as the number of interconnect levels are increased. It may be desirable to provide devices with improved reliability regarding reducing the potential for dielectric breakdown and/or electrical shorting between adjacent metal layers.

### SUMMARY

Embodiments of the present disclosure relate to a semiconductor device. The semiconductor device includes a substrate, a plurality of metal lines on the substrate, a plurality of top vias formed on the plurality of metal lines, and a dielectric liner layer formed on at least portions of the top vias.

Embodiments of the present disclosure relate to an electronic device. The electronic device includes a semiconductor device that includes a substrate, a plurality of metal lines on the substrate, a plurality of top vias formed on the plurality of metal lines, and a dielectric liner layer formed on at least portions of the top vias.

Embodiments of the present disclosure relate to a semiconductor device. The semiconductor device includes a substrate, a plurality of metal lines on the substrate, a plurality of top vias formed on the plurality of metal lines, and an airgap surrounding at least a portion of sidewalls of at least one of the top vias.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 is a partial cross-sectional view of a semiconductor device having a top via with a dielectric encapsulating sidewall liner material, at an intermediate stage of the fabrication process, according to embodiments.

FIG. 2 is a partial cross-sectional view of the semiconductor device of FIG. 1 at subsequent stage of the fabrication process, according to embodiments.

FIG. 3 is a partial cross-sectional view of the semiconductor device of FIG. 2 at subsequent stage of the fabrication process, according to embodiments.

FIG. 4 is a partial cross-sectional view of the semiconductor device of FIG. 3 at subsequent stage of the fabrication process, according to embodiments.

FIG. 5 is a partial cross-sectional view of the semiconductor device of FIG. 4 at subsequent stage of the fabrication process, according to embodiments.

FIG. 6 is a partial cross-sectional view of the semiconductor device of FIG. 5 at subsequent stage of the fabrication process, according to embodiments.

FIG. 7 is a partial cross-sectional view of the semiconductor device of FIG. 6 at subsequent stage of the fabrication process, according to embodiments.

FIG. 8 is a partial cross-sectional view of a semiconductor device having a top via with a first dielectric encapsulating sidewall liner material and metal lines with a second dielectric encapsulating sidewall liner material, at an intermediate stage of the fabrication process, according to embodiments.

FIG. 9 is a partial cross-sectional view of the semiconductor device of FIG. 8 at a subsequent stage of the fabrication process, according to embodiments.

FIG. 10 is a partial cross-sectional view of the semiconductor device of FIG. 9 at a subsequent stage of the fabrication process, according to embodiments.

FIG. 11 is a partial cross-sectional view of the semiconductor device of FIG. 10 at a subsequent stage of the fabrication process, according to embodiments.

FIG. 12 is a partial cross-sectional view of the semiconductor device of FIG. 11 at a subsequent stage of the fabrication process, according to embodiments.

FIG. 13 is a partial cross-sectional view of the semiconductor device of FIG. 12 at a subsequent stage of the fabrication process, according to embodiments.

FIG. 14 is a partial cross-sectional view of the semiconductor device of FIG. 13 at a subsequent stage of the fabrication process, according to embodiments.

FIG. 15 is a partial cross-sectional view of the semiconductor device of FIG. 14 at a subsequent stage of the fabrication process, according to embodiments.

FIG. 16 is a partial cross-sectional view of the semiconductor device of FIG. 15 at a subsequent stage of the fabrication process, according to embodiments.

FIG. 17 is a partial cross-sectional view of the semiconductor device of FIG. 16 at a subsequent stage of the fabrication process, according to embodiments.

FIG. 18 is a partial cross-sectional view of the semiconductor device of FIG. 16 at a subsequent stage of the fabrication process, according to embodiments.

FIG. 19 is a partial cross-sectional view of a semiconductor device having a top via with a dielectric encapsulating sidewall liner material and metal lines surrounded by airgaps, according to embodiments.

FIG. 20 is a partial cross-sectional view of a semiconductor device having a first plurality of top vias with a dielectric encapsulating sidewall liner material and a second plurality of top vias with a metallic sidewall liner material, according to embodiments.

FIG. 21 is a partial cross-sectional view of a semiconductor device having a top via with airgaps surrounding at least a portion thereof, according to embodiments.

### DETAILED DESCRIPTION

The present disclosure describes semiconductor devices. More specifically, the present disclosure relates to interconnect structures including top vias having different dielectric materials, metal materials, and/or airgaps surrounding at least a portion thereof. The present disclosure also provides methods of fabricating such interconnect structures.

The flowcharts and cross-sectional diagrams in the Figures illustrate methods of manufacturing semiconductor devices according to various embodiments. In some alternative implementations, the manufacturing steps may occur in a different order than that is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the particular drawing figures. Several of the figures show different orientation such as the top view, and different cross-sectional views. It should be noted that right and left, or top and bottom, etc. relate to (or depend on) the particular view of each figure. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure,

The present embodiments provide improved structures and methods of fabricating same which may reduce the potential for electrical shorting and dielectric breakdown between various metal layers of the semiconductor device.

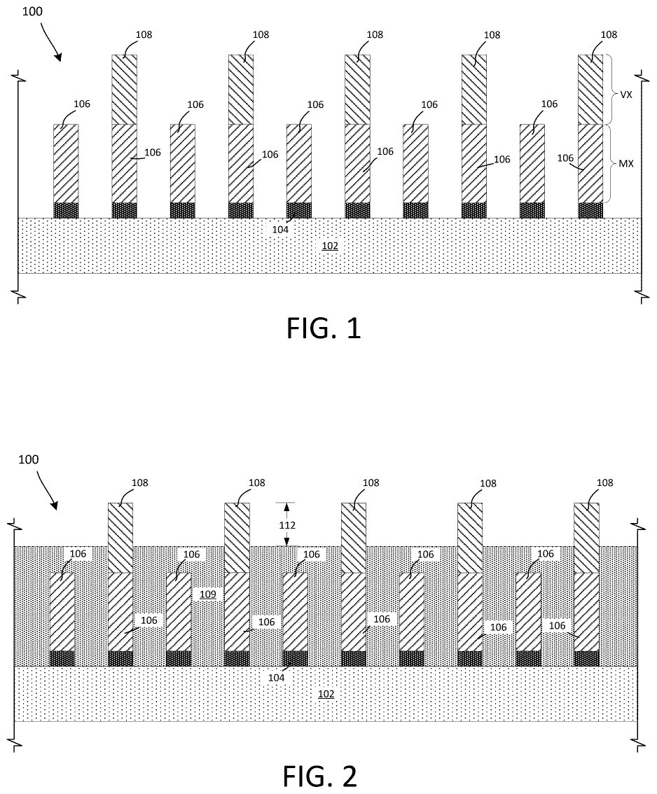

Referring now to the drawings in which like numerals represent the same or similar elements and initially to FIG. 1, this figure is a partial cross-sectional view of a semiconductor device 100 at an intermediate stage of the fabrication process, according to embodiments. As shown in FIG. 1, a substrate 102 is provided. The substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate. Other illustrative examples of semiconductor materials that can be used in the present application include, but are not limited to, silicon (Si), a silicon germanium (SiGe) alloy, a silicon germanium carbide (SiGeC) alloy, germanium (Ge), a III/V compound semiconductor, an II/VI compound semiconductor or a multilayered stack including at least two semiconductor materials (e.g., a multilayered stack of Si and SiGe). In one embodiment (depicted in the drawings of the present application), the semiconductor substrate 102 is entirely composed of at least one semiconductor material. When the substrate 102 is an insulating material, the insulating material can be an organic insulator, an inorganic insulator or a combination thereof including multilayers. The substrate 102 may also include a patternable low-κ dielectric material as well. When the substrate 102 is a conducting material, the substrate may include, for example, polySi, an elemental metal, alloys of elemental metals, a metal silicide, a metal nitride, conductive nanotubes and nanowires or combinations thereof including multilayers. When the substrate 102 comprises a semiconducting material, one or more semiconductor devices such as, for example, complementary metal oxide semiconductor (CMOS) devices can be fabricated thereon. It should be appreciated that the substrate 102 may be comprised of any other suitable material(s) than those listed above.

Referring again to FIG. 1, the semiconductor device 100 includes an underlayer 104 formed on the substrate under a plurality of metal lines 106. In certain embodiments, the underlayer 104 may comprise TaN, TiN, etc. In certain embodiments, the underlayer 104 may be omitted. On certain of the metal lines 106 top vias 108 are formed. In certain embodiments, the metal lines 106 and the top vias 108 are formed by a subtractive method and may comprise, for example, Ru. In other embodiments, the metal lines 106 and top vias 108 may be formed by a via fill and etching process applied to an interlayer dielectric (ILD) layer (not shown). It should be appreciated that the metal lines 106 and top vias 108 may be formed by any suitable combination of patterning, lithography, deposition, and material removal processes. In certain embodiments, the metal lines 106 and top vias 108 comprise, for example Cu or Ru, however any suitable electrically conductive materials may be used. In certain examples, the metal lines 106 are present in a Mx metal interconnect layer. In the context of semiconductor technology, an “Mx layer” typically refers to metal layers within integrated circuits (ICs) used for interconnects, with “M” representing a metal (like Ru, Cu, W, etc.) and “x” potentially being a dielectric or other insulating material. These layers enable wiring and electrical connections between different components on a chip. In certain examples, the top vias 108 are formed on top of certain of the metal lines 106 and may be formed in a Vx metal interconnect layer. In semiconductor fabrication, a “Vx layer” generally refers to a specific layer used in the construction of integrated circuits or other microelectronic devices, often a metal layer with vias (e.g., the top vias 108 shown in FIG. 1) that connects to other layers, such as in high-density memory structures. The top vias 108 are small conductive paths that connect different layers of the semiconductor device 100, enabling electrical communication between, for example, transistors and other components.

Referring now to FIG. 2, this figure is a partial cross-sectional view of the semiconductor device 100 of FIG. 1 at subsequent stage of the fabrication process, according to embodiments. As shown in FIG. 2, a sacrificial gap fill layer 109 is deposited to fill in the spaces between the metal lines 106. In certain examples, the sacrificial gap fill layer 109 may comprise a spin on glass (SOG) insulator, a furnace chemical vapor deposition (FCVD) material, etc. In certain embodiments, as shown in FIG. 2, the top surface of the sacrificial gap fill layer 109 is formed to be above the top surface of the metal lines 106, but also below the top surface of the top via 108. In this way, the upper portions of the top vias 108 are exposed for further processing. In certain embodiments, the exposed portion of the top vias 108 may have a top via height 112 ranging from about 5-30 nm. In certain examples, the sacrificial gap fill layer 109 may initially be formed in excess to cover the top surfaces of the top vias 108. In these examples, excess material of the sacrificial gap fill layer 109 may be subsequently removed with any suitable material removal process down to the level of the top surface of the top vias 108 to planarize the overall surface of the semiconductor device 100. Then, another material removal process may be used to selectively remove more of the material of the sacrificial gap fill layer 109 so that this layer is recessed relative to the top surfaces of the top vias 108. In certain examples, a width of the metal lines 106 and the top vias 108 may range from about 5-10 nm, a distance between the metal lines 106 may be from about 5-10 nm, the pitch of the metal lines 106 may be about 10-20 nm, and the height of the metal lines 106 may be about 20-40 nm. However, it should be appreciated that other suitable dimensions for these layers may be used. As will be described in further detail below, after the sacrificial gap fill layer 109 is later removed, there will again be empty space between the adjacent metal lines 106. In certain embodiments, the sacrificial gap fill layer 109 may comprise any suitable dielectric material.

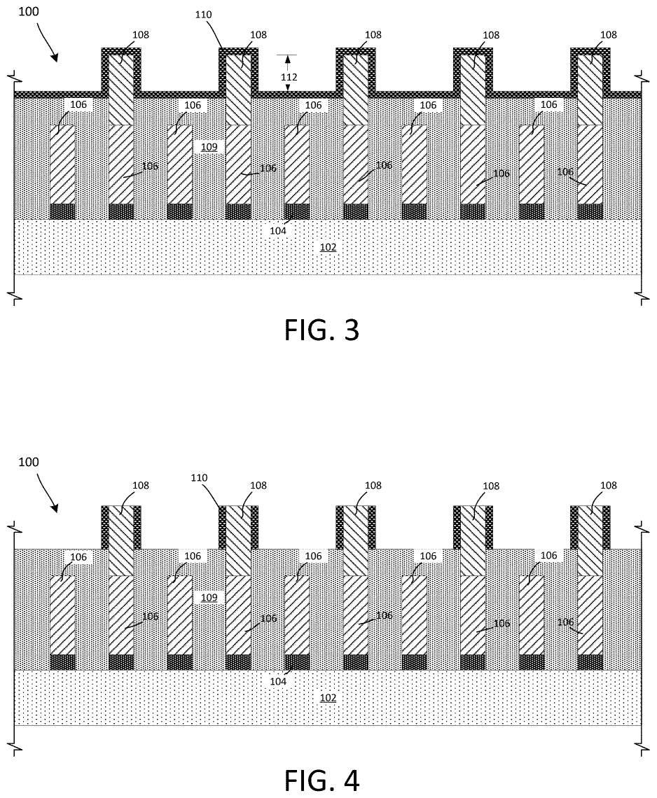

Referring now to FIG. 3, this figure is a partial cross-sectional view of the semiconductor device 100 of FIG. 2 at subsequent stage of the fabrication process, according to embodiments. As shown in FIG. 3, a dielectric liner layer 110 is conformally deposited over the entire surface of the semiconductor device 100. Thus, at this stage in the manufacturing process, the dielectric liner layer 110 covers the top surface of the sacrificial gap fill layer 109 as well as the top and sidewall surfaces of the exposed portions of the top vias 108. In certain embodiments, the dielectric liner layer 110 comprises one or more dielectric materials having a higher dielectric constant (e.g., 3<κ<10) than that of the sacrificial gap fill layer 109. In certain embodiments, the dielectric liner layer 110 comprises, for example, SiN, SiOₓ, HfOₓ, AlOₓ, AlN, etc.).

Referring now to FIG. 4, this figure is a partial cross-sectional view of the semiconductor device 100 of FIG. 3 at subsequent stage of the fabrication process, according to embodiments. As shown in FIG. 4, a suitable material removal process (e.g., anisotropic etching) is performed to remove the horizontal portions of the dielectric liner layer 110, thus leaving only the sidewall portions of the dielectric liner layer 110 remaining. These sidewall portions of the dielectric liner layer 110 may also be referred to as sidewall spacers or a top via encapsulation layer.

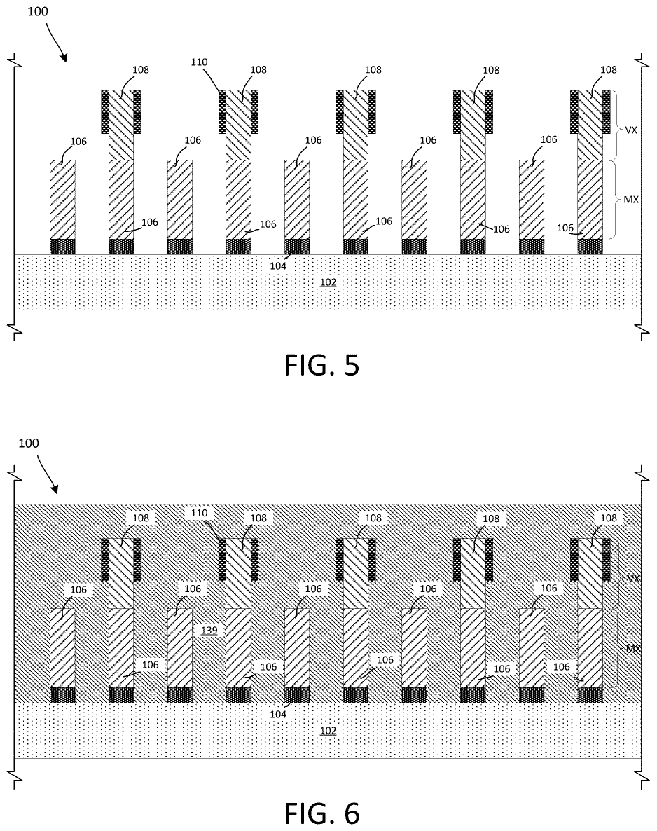

Referring now to FIG. 5, this figure is a partial cross-sectional view of the semiconductor device 100 of FIG. 4 at subsequent stage of the fabrication process, according to embodiments. As shown in FIG. 5, a suitable material removal process (e.g., wet etching or dry etching) is performed to remove the sacrificial gap fill layer 109. Thus, after the removal of the sacrificial gap fill layer 109, there are spaces between adjacent metal lines 106 and top vias 108.

Referring now to FIG. 6, this figure is a partial cross-sectional view of the semiconductor device 100 of FIG. 5 at subsequent stage of the fabrication process, according to embodiments. As shown in FIG. 6, a material deposition process is performed to create an interlayer dielectric (ILD) layer 139 between the metal lines 106, between the top vias 108, and between the dielectric liner layer 110. It should be appreciated that any suitable dielectric material(s) may be used to form the ILD layer 139. In certain embodiments, the ILD layer 139 may initially be formed in excess to a thickness that completely covers the top surfaces of the top vias 108 and the top surfaces of the dielectric liner layer 110.

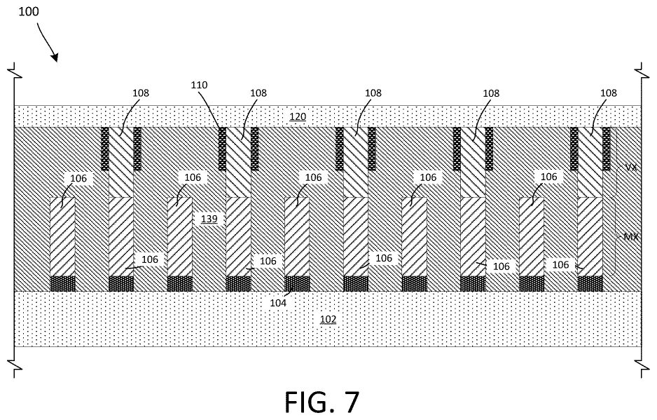

Referring now to FIG. 7, this figure is a partial cross-sectional view of the semiconductor device 100 of FIG. 6 at subsequent stage of the fabrication process, according to embodiments. As shown in FIG. 7, after the deposition of the ILD layer 139, a suitable material removal process (e.g., CMP) is performed to planarize the top surface of the semiconductor device 100 and to remove excess material of the ILD layer 139 to expose the top surfaces of the top vias 108 and the top surfaces of the dielectric liner layer 110. Then, as shown in FIG. 7, a capping layer 120 is formed on the top of the ILD layer 139. The capping layer 120 may comprise any suitable dielectric material(s).

Although not shown in FIGS. 1-7, additional metal interconnect layers (e.g., an Mₓ₊₁ layer) may be formed on top of the Vₓ layer. In the example of the Mₓ₊₁ layer, additional Mₓ₊₁ metal lines (not shown) are formed that electrically connect to (or directly contact) certain of the top vias 108. Because of the small dimensions associated with the different structural features of the semiconductor device 100, these Mₓ₊₁ metal lines may have a certain amount of misalignment present with respect to the top vias 108. This could potentially present problems regarding electrical shorting or dielectric breakdown when one of the Mₓ₊₁ metal lines is too close to a neighboring top via 108. However, in the present embodiments, the presence of the dielectric liner layer 110 surrounding at least portions of the top vias 108 creates a relatively high-κ (high κ-value or dielectric constant) barrier that may mitigate or eliminate the potential for electrical shorting or dielectric breakdown. It should be appreciated that although FIGS. 1-7 show that all the top vias 108 include the dielectric liner layer 110, it is not necessary that all the top vias 108 include this layer (i.e., for some of the top vias 108, the dielectric liner layer 110 may be omitted).

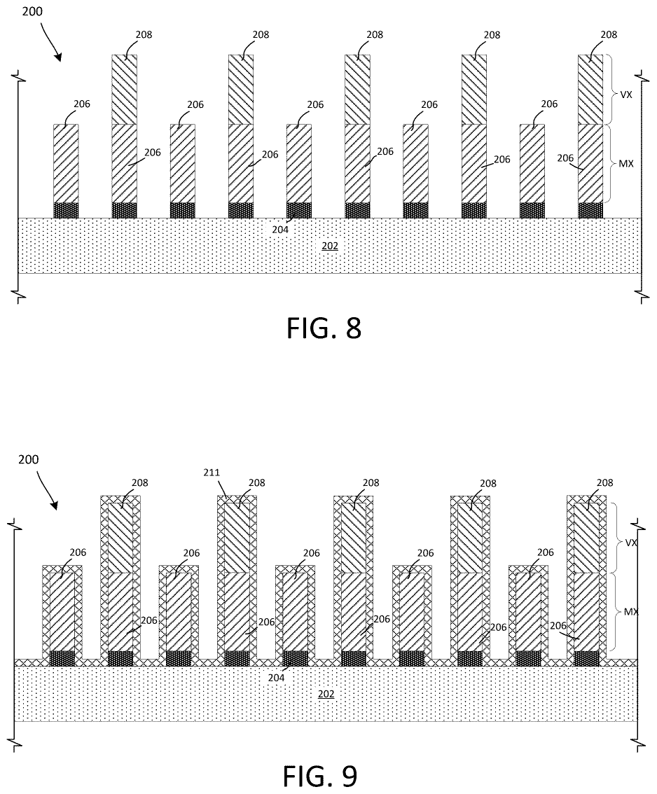

Referring now to FIG. 8, this figure is a partial cross-sectional view of a semiconductor device 200 with an additional spacer layer 211 formed on sidewalls of the metal lines 206. As shown in FIG. 8, a substrate 202 is provided. The substrate 202 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 202 may also be a semiconductor on insulator (SOI) substrate. Other illustrative examples of semiconductor materials that can be used in the present application include, but are not limited to, silicon (Si), a silicon germanium (SiGe) alloy, a silicon germanium carbide (SiGeC) alloy, germanium (Ge), a III/V compound semiconductor, an II/VI compound semiconductor or a multilayered stack including at least two semiconductor materials (e.g., a multilayered stack of Si and SiGe). In one embodiment (depicted in the drawings of the present application), the semiconductor substrate 202 is entirely composed of at least one semiconductor material. When the substrate 202 is an insulating material, the insulating material can be an organic insulator, an inorganic insulator or a combination thereof including multilayers. The substrate 202 may also include a patternable low-κ dielectric material as well. When the substrate 202 is a conducting material, the substrate may include, for example, polySi, an elemental metal, alloys of elemental metals, a metal silicide, a metal nitride, conductive nanotubes and nanowires or combinations thereof including multilayers. When the substrate 202 comprises a semiconducting material, one or more semiconductor devices such as, for example, complementary metal oxide semiconductor (CMOS) devices can be fabricated thereon. It should be appreciated that the substrate 202 may be comprised of any other suitable material(s) than those listed above.

Referring again to FIG. 8, the semiconductor device 200 includes an underlayer 204 formed on the substrate under a plurality of metal lines 206. In certain embodiments, the underlayer 204 may comprise TaN. In certain embodiments, the underlayer 204 may be omitted. On certain of the metal lines 206 top vias 208 are formed. In certain embodiments, the metal lines 206 and the top vias 208 are formed by a subtractive method and may comprise, for example, Ru. In other embodiments, the metal lines 206 and top vias 208 may be formed by a via fill and etching process applied to an interlayer dielectric (ILD) layer (not shown). It should be appreciated that the metal lines 208 and top vias 208 may be formed by any suitable combination of patterning, lithography, deposition, and material removal processes. In certain embodiments, the metal lines 206 and top vias 208 comprise, for example Cu or Ru, however any suitable electrically conductive materials may be used. In certain examples, the metal lines 206 are present in a Mₓ metal interconnect layer. In certain examples, the top vias 208 are formed on top of certain of the metal lines 206 and may be formed in a Vₓ metal interconnect layer. The top vias 208 are small conductive paths that connect different layers of the semiconductor device 200, enabling electrical communication between, for example, transistors and other components.

Referring now to FIG. 9, this figure is a partial cross-sectional view of a semiconductor device 200 at an intermediate stage of the fabrication process, according to embodiments. As shown in FIG. 9, a spacer layer 211 is conformally deposited on the substrate 202 and all exposed surfaces of the underlayer 204, the metal lines 206, and the top vias 208. In certain examples, the liner layer 205 may comprise SiN. However, it should be appreciated that any suitable material(s) may be used for the liner layer 205. In certain examples, the material of the spacer layer 211 may be a dielectric layer, and in other examples it may be a conductive material. In the examples where the spacer layer 211 comprises a high-κ dielectric material it may improve the reliability between two adjacent metal lines 206 in the Mₓ layer by minimizing the potential for electrical shorting or dielectric breakdown. In other examples, the material of the spacer layer 211 may be a conducting metal. In these examples, the metal material may function as a barrier to reduce or minimize reliability issues related to electrical migration. In examples where the metal lines 206 comprise copper, the conductive metal material of the spacer layer 211 may be, for example, Ta, TaN, Co, etc., and this may function as a barrier layer to help prevent electrical migration from the Cu to an interlayer dielectric (ILD) layer. In examples where the metal lines 206 comprise Ruthenium, the material of the spacer layer 211 may be a dielectric material.

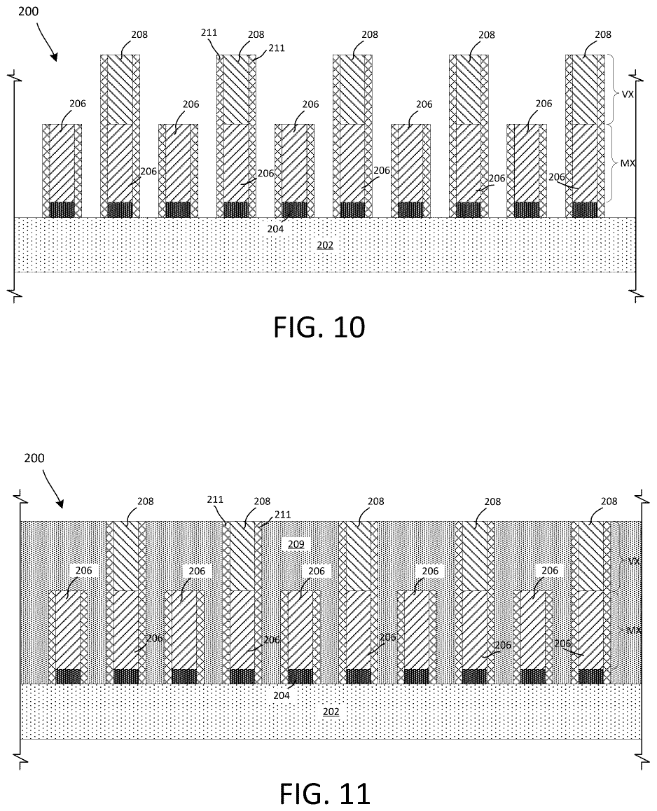

Referring now to FIG. 10, this figure is a partial cross-sectional view of the semiconductor device 200 of FIG. 9 at subsequent stage of the fabrication process, according to embodiments. As shown in FIG. 10, a suitable material removal process (e.g., anisotropic etching) is performed to remove the horizontal portions of the spacer layer 211, thus leaving only the sidewall portions of the spacer layer 211 remaining. These sidewall portions of the spacer layer 211 may also be referred to as sidewall spacers or a metal line encapsulation layer.

Referring now to FIG. 11, this figure is a partial cross-sectional view of the semiconductor device 200 of FIG. 10 at subsequent stage of the fabrication process, according to embodiments. As shown in FIG. 11, a sacrificial gap fill layer 209 is deposited to fill in the spaces between the metal lines 206 and between the top vias 208. In certain examples, the sacrificial gap fill layer 109 may comprise a spin on glass (SOG) insulator, a furnace chemical vapor deposition (FCVD) material, etc. In certain examples, the sacrificial gap fill layer 209 may initially be formed in excess to cover the top surfaces of the top vias 208. In these examples, excess material of the sacrificial gap fill layer 209 may be subsequently removed with any suitable material removal process down to the level of the top surface of the top vias 208 to planarize the overall surface of the semiconductor device 200.

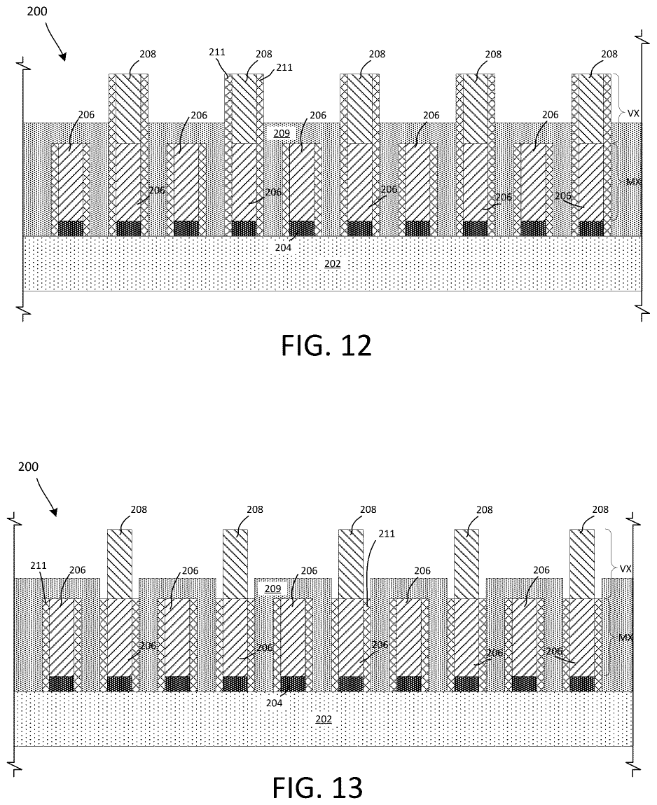

Referring now to FIG. 12, this figure is a partial cross-sectional view of the semiconductor device 200 of FIG. 11 at subsequent stage of the fabrication process, according to embodiments. As shown in FIG. 12, a suitable material removal process may be used to selectively remove more of the material of the sacrificial gap fill layer 209 so that this layer is recessed relative to the top surfaces of the top vias 208. In certain examples, a width of the metal lines 206 and the top vias 208 may range from about 5-10 nm, a distance between the metal lines 206 may be from about 5-10 nm, the pitch of the metal lines 206 may be about 10-20 nm, and the height of the metal lines 206 may be about 20-40 nm. However, it should be appreciated that other suitable dimensions for these layers may be used. The heights, widths, and pitch between adjacent metal lines 206 may be the same or different as in the embodiments related to FIGS. 1-7.

Referring now to FIG. 13, this figure is a partial cross-sectional view of the semiconductor device 200 of FIG. 12 at subsequent stage of the fabrication process, according to embodiments. As shown in FIG. 13, after the excess material of the sacrificial gap fill layer 209 has been removed, a suitable etching process is performed that is selective to the spacer layer 211 relative to the sacrificial gap fill layer 209 so that portions of the spacer layer adjacent to the top vias 208 are recessed. In certain embodiments, these spacer layer 211 is recessed down to at or about the level of the top surfaces of the metal lines 206.

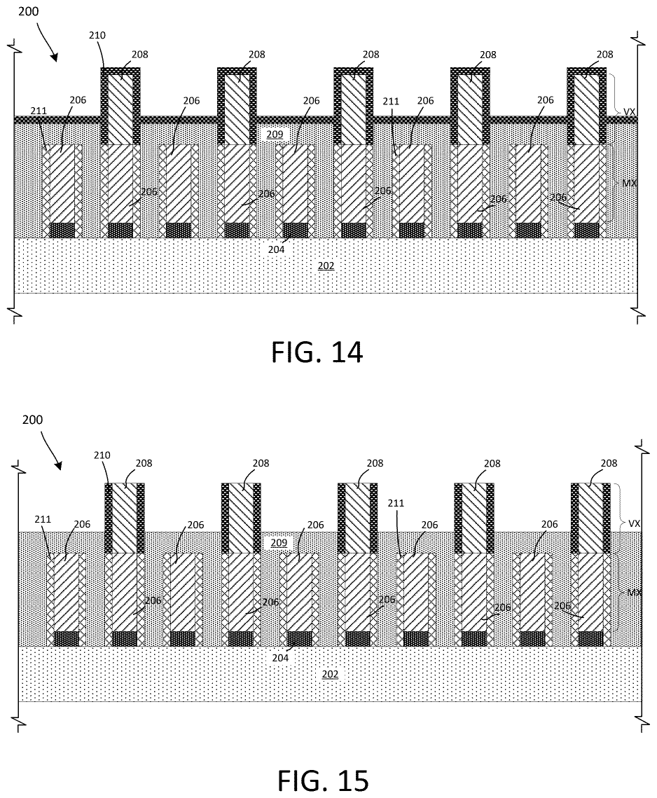

Referring now to FIG. 14, this figure is a partial cross-sectional view of the semiconductor device 200 of FIG. 13 at subsequent stage of the fabrication process, according to embodiments. As shown in FIG. 14, a dielectric liner layer 210 is conformally deposited over the entire surface of the semiconductor device 200. Thus, at this stage in the manufacturing process, the dielectric liner layer 210 covers the top surface of the sacrificial gap fill layer 209 as well as the top and sidewall surfaces of the exposed portions of the top vias 208. Due to the recessing of the spacer layer 211 described above with respect to FIG. 13, the dielectric liner layer 210 also fills in these recessed areas to cover the top surfaces of the spacer layer 211. In certain embodiments, the dielectric liner layer 210 comprises one or more dielectric materials having a higher dielectric constant (e.g., 3<κ<10) than that of the sacrificial gap fill layer 209. In certain embodiments, the dielectric liner layer 210 comprises, for example, SiN, SiOₓ, HfOₓ, AlOₓ, AlN, etc.). In certain embodiments, the material of the dielectric liner layer 210 is different than the material of the spacer layer 211.

Referring now to FIG. 15, this figure is a partial cross-sectional view of the semiconductor device 200 of FIG. 14 at subsequent stage of the fabrication process, according to embodiments. As shown in FIG. 15, a suitable material removal process (e.g., anisotropic etching) is performed to remove the horizontal portions of the dielectric liner layer 210, thus leaving only the sidewall portions of the dielectric liner layer 210 remaining. These sidewall portions of the dielectric liner layer 210 may also be referred to as sidewall spacers or a top via encapsulation layer.

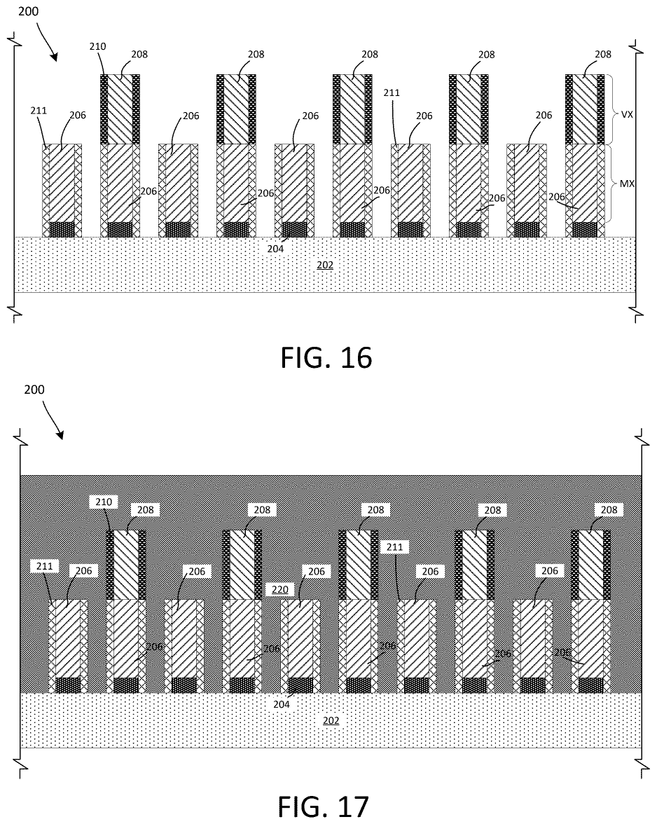

Referring now to FIG. 16, this figure is a partial cross-sectional view of the semiconductor device 200 of FIG. 15 at subsequent stage of the fabrication process, according to embodiments. As shown in FIG. 16, a suitable material removal process (e.g., wet etching or dry etching) is performed to remove the sacrificial gap fill layer 209. Thus, after the removal of the sacrificial gap fill layer 209, there are spaces between adjacent metal lines 206 and top vias 208.

Referring now to FIG. 17, this figure is a partial cross-sectional view of the semiconductor device 200 of FIG. 16 at subsequent stage of the fabrication process, according to embodiments. As shown in FIG. 17, a material deposition process is performed to create an interlayer dielectric (ILD) layer 220 between the metal lines 206, between the top vias 208, between the spacer layer 211, and between the dielectric liner layer 210. It should be appreciated that any suitable dielectric material(s) may be used to form the ILD layer 220. In certain embodiments, the ILD layer 220 may initially be formed in excess to a thickness that completely covers the top surfaces of the top vias 208 and the top surfaces of the dielectric liner layer 210.

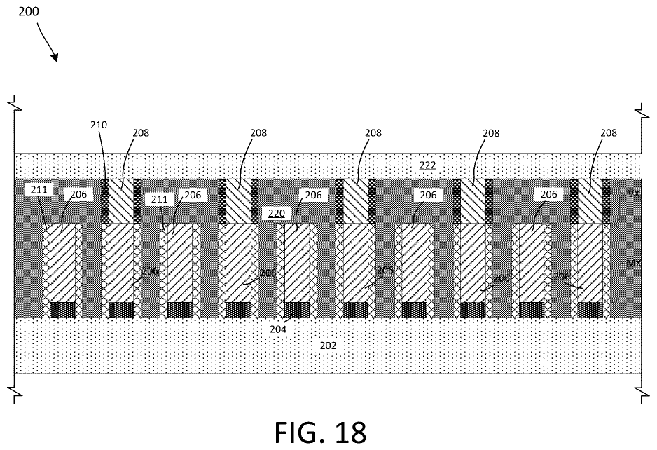

Referring now to FIG. 18, this figure is a partial cross-sectional view of the semiconductor device 100 of FIG. 17 at subsequent stage of the fabrication process, according to embodiments. As shown in FIG. 18, after the deposition of the ILD layer 220, a suitable material removal process (e.g., CMP) is performed to planarize the top surface of the semiconductor device 200 and to remove excess material of the ILD layer 220 to expose the top surfaces of the top vias 208 and the top surfaces of the dielectric liner layer 210. Then, as shown in FIG. 18, a capping layer 222 is formed on the top of the ILD layer 220. The capping layer 222 may comprise any suitable dielectric material(s).

Although not shown in FIGS. 8-18, additional metal interconnect layers (e.g., an Mₓ₊₁ layer) may be formed on top of the Vₓ layer. In the example of the Mₓ₊₁ layer, additional Mₓ₊₁ metal lines (not shown) are formed that electrically connect to (or directly contact) certain of the top vias 208. Because of the small dimensions associated with the different structural features of the semiconductor device 200, these Mₓ₊₁ metal lines may have a certain amount of misalignment present with respect to the top vias 208. This could potentially present problems regarding electrical shorting or dielectric breakdown when one of the Mₓ₊₁ metal lines is too close to a neighboring top via 208. However, in the present embodiments, the presence of the dielectric liner layer 210 surrounding at least portions of the top vias 208 creates a relatively high-κ barrier that may mitigate or eliminate the potential for electrical shorting or dielectric breakdown. Also, as mentioned above, the material of the spacer layer 211 may function as a barrier to reduce or minimize reliability issues related to electrical migration (e.g., in the case that the metal lines are Cu and the spacer layer 211 is a conductive material), or it may help minimize dielectric breakdown or electrical shorting (e.g., in the case that the spacer layer 211 is a high-κ dielectric material). It should be appreciated that although FIGS. 8-18 show that all the top vias 208 include the dielectric liner layer 210, it is not necessary that all the top vias 208 include this layer (i.e., for some of the top vias 208, the dielectric liner layer 210 may be omitted). It should also be appreciated that although FIGS. 8-18 show that all the metal lines 206 include the spacer layer 211, it is not necessary that all the metal lines 206 include this layer (i.e., for some of the metal lines 206, the spacer layer 211 may be omitted).

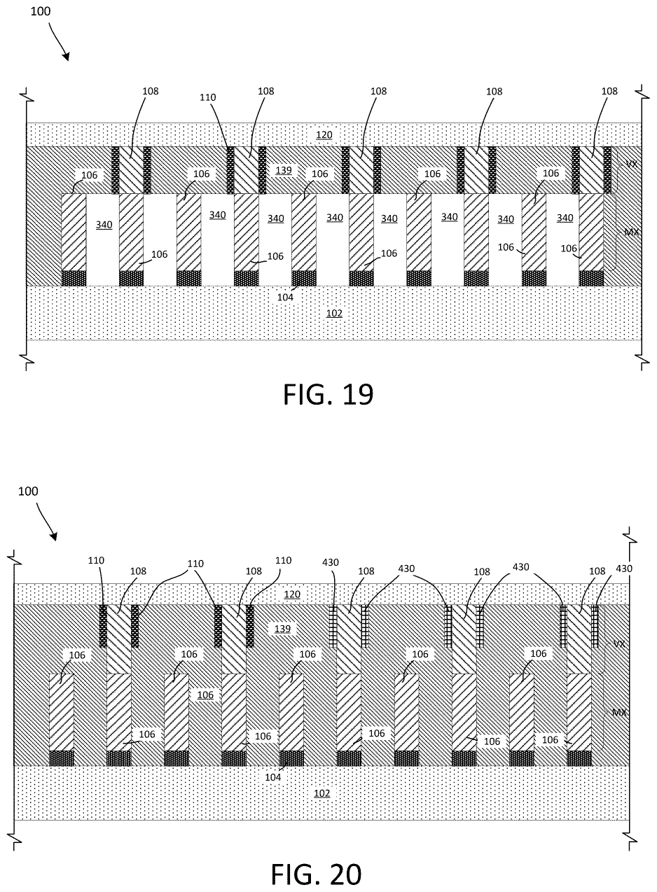

Referring now to FIG. 19, this figure is a partial cross-sectional view of a semiconductor device 100, according to embodiments. As shown in FIG. 19, this embodiment differs from the embodiments of FIGS. 1-7 in that airgaps 340 are formed between adjacent metal lines 106.

Referring now to FIG. 20, this figure is a partial cross-sectional view of a semiconductor device 100, according to embodiments. As shown in FIG. 20, this embodiment differs from the embodiments of FIGS. 1-7 in that some of the top vias 108 are covered in the dielectric liner layer 110 and other of the top vias 108 are covered in a metallic liner layer 430. One reason for using a metallic liner layer is to increase the contact area of the Vₓ to Mₓ₊₁ boundary and hence reduce the contact resistance at this interface. It should be appreciated that the position and arrangement of the dielectric liner layer 110 and the metallic liner layer 430 shown in FIG. 19 is only one example, and in other examples these do not have to be adjacent to one another and may be location on physically separate portion of the semiconductor device 100. It should also be appreciated that the length, depth and/or thickness of the dielectric liner layer 110 and the metallic liner layer 430 may be different or the same.

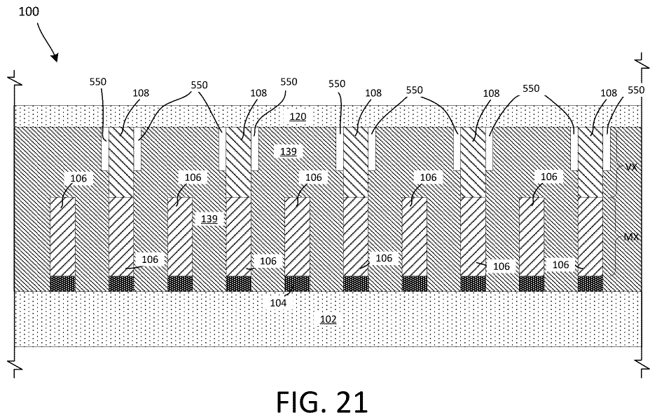

Referring now to FIG. 21, this figure is a partial cross-sectional view of a semiconductor device 100, according to embodiments. As shown in FIG. 21, this embodiment differs from the embodiments of FIGS. 1-7 in that airgaps 550 are formed around the top vias 108 rather than the dielectric liner layer 110 shown in FIG. 7. In certain embodiments, the dielectric liner layer 110 could first be formed and then later removed with a suitable etching process before the formation of the capping layer 120.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a substrate;
a plurality of metal lines on the substrate;
a plurality of top vias formed on the plurality of metal lines; and
a dielectric liner layer formed on at least a portion of sidewalls of at least one of the plurality of top vias.

2. The semiconductor device of claim 1, wherein the plurality of metal lines comprise Ru.

3. The semiconductor device of claim 1, wherein a bottom surface of the dielectric liner layer is above a top surface of the plurality of metal lines.

4. The semiconductor device of claim 1, further comprising an interlayer dielectric (ILD) layer between the plurality of metal lines and between the plurality of top vias.

5. The semiconductor device of claim 4, wherein the dielectric liner layer is comprised of a different material than that of the ILD layer.

6. The semiconductor device of claim 4, wherein the dielectric liner layer is comprised of a material having a higher κ value than that of the ILD layer.

7. The semiconductor device of claim 1, wherein the plurality of metal lines are formed within an Mₓ layer.

8. The semiconductor device of claim 1, wherein the plurality of top vias are formed within a Vₓ layer.

9. The semiconductor device of claim 1, further comprising a spacer layer formed on sidewalls of at least one of the plurality of metal lines.

10. The semiconductor device of claim 9, wherein the spacer layer is a conductive material.

11. The semiconductor device of claim 9, wherein the spacer layer is a dielectric material.

12. The semiconductor device of claim 1, further comprising a metallic liner layer formed on at least a portion of sidewalls of at least one of the plurality of top vias.

13. The semiconductor device of claim 1, wherein airgaps exist between adjacent ones of the plurality of metal lines.

14. An electronic device comprising:
semiconductor device including:
a substrate;
a plurality of metal lines on the substrate;
a plurality of top vias formed on the plurality of metal lines; and
a dielectric liner layer formed on at least a portion of sidewalls of at least one of the plurality of top vias.

15. The electronic device of claim 14, wherein the plurality of metal lines comprise Ru.

16. The electronic device of claim 14, wherein a bottom surface of the dielectric liner layer is above a top surface of the plurality of metal lines.

17. The electronic device of claim 14, further comprising an interlayer dielectric (ILD) layer between the plurality of metal lines and between the plurality of top vias.

18. The electronic device of claim 17, wherein the dielectric liner layer is comprised of a different material than that of the ILD layer.

19. The electronic device of claim 17, wherein the dielectric liner layer is comprised of a material having a higher κ value than that of the ILD layer.

20. A semiconductor device comprising:
a substrate;
a plurality of metal lines on the substrate;
a plurality of top vias formed on the plurality of metal lines; and
an airgap surrounding at least a portion of sidewalls of at least one of the plurality of top vias.
